(19) United States
(12) Patent Application Publication
(10) Pub. No.: US 2016/0079559 A1
(43) Pub. Date: Mar. 17, 2016

(54) ROLL OF GAS-BARRIER FILM, AND PROCESS FOR PRODUCING GAS-BARRIER FILM

(71) Applicant: Konica Minolta, Inc., Chiyoda-ku, Tokyo (JP)

(72) Inventor: Takahiro MORI, Tokyo (JP)

(21) Appl. No.: 14/779,799

(22) PCT Filed: Mar. 21, 2013
(86) PCT No.: PCT/JP2013/001904

§ 371 Date: Sep. 24, 2015

(51) Int. Cl. H01L 51/52; C23C 16/513

(52) U.S. Cl. CPC H01L 51/5237; C23C 16/513

(57) ABSTRACT

A roll of a gas barrier film may be obtained by winding a gas barrier film including a base and a gas barrier layer in a direction orthogonal to a width of the film. The gas barrier layer may contain silicon, oxygen, and carbon atoms. A surface of the base, opposite to a side of the gas barrier layer, may have protrusions A having a height of 10 nm or more and less than 100 nm from a roughness center plane at a density of 500 to 10,000/mm², and protrusions B having a height of 100 nm or more from a roughness center plane at a density of 0 to 500/mm². The base may have a haze of 1% or less measured in accordance with JIS K-7136. A flatness index defined as the number of sites raised 1 mm or more is within a range of from 0 to 5.

### TECHNICAL FIELD

The present invention relates to a roll of a gas barrier film, and a process for producing a gas barrier film.

### BACKGROUND ART

Gas barrier films have been used as a gas barrier substrate and a sealing substrate for flexible electronic devices such as flexible organic EL displays. Such gas barrier films are required to have high gas barrier properties even in the bent form.

For such gas barrier films, gas barrier films have been proposed which include a base layer and a gas barrier layer containing silicon atoms, oxygen atoms and carbon atoms, wherein a carbon atom distribution curve with the distance from the surface as X value and the content ratio of carbon atoms to (silicon atoms+oxygen atoms+carbon atoms) as Y value has an extreme value (e.g., PTLs 1 and 2). The gas barrier layer of the gas barrier film is disclosed as being formed by a specific plasma CVD film-forming apparatus illustrated in FIG. 3, for example.

FIG. 3 is a schematic view illustrating the basic configuration of the plasma CVD film-forming apparatus. As illustrated in FIG. 3, film-forming apparatus 30 has a vacuum chamber (not illustrated), and a pair of film-forming rolls 31 and 33 that is disposed inside the vacuum chamber and that conveys an elongated base. A gas barrier thin film is formed on the base facing a film-forming space formed between the pair of film-forming rolls 31 and 33.

It is also important that electronic devices including a gas barrier film have not only high gas barrier properties, but also excellent flatness without wrinkles and the like. In particular, large-sized electronic devices having a gas barrier film with poor flatness are likely to distort the electronic device.

One exemplary method of sealing an organic EL display device is a surface sealing (solid sealing) method. In the surface sealing (solid sealing) method, a sealing substrate is attached to organic EL elements with a liquid adhesive or sheet-like adhesive to seal the organic EL elements (see, e.g., PTLs 3 and 4). Poor flatness of the gas barrier film or sealing substrate may result in the generation of wrinkles upon attachment. The wrinkles upon attachment are likely to occur particularly in large-sized organic EL display devices.

### CITATION LIST

### Patent Literature

### PTL 1

### Japanese Patent Application Laid-Open No. 2012-97354

### PTL 2

### Japanese Patent Application Laid-Open No. 2012-82468

### PTL 3

### Japanese Patent Application Laid-Open No. 2002-216950

### PTL 4

### Japanese Patent Application Laid-Open No. 2011-031472

### SUMMARY OF INVENTION

### Technical Problem

The gas bather films disclosed in PTLs 1 and 2 have the problem of poor film flatness.

The presumed cause of poor film flatness is as follows, although the cause is not necessarily clear. That is, in film-forming apparatus 30 illustrated in FIG. 3, the wrap angle around film-forming rolls 31 and 33 is large, and thus the contact area between the rear surface of the base and the film-forming rolls 31 and 33 is large. Therefore, the base is unlikely to slide on the film-forming roll, and thus the tension applied to the base is likely to be non-uniform. The non-uniform tension applied to the base is likely to cause the base to be elongated non-uniformly, or causes the adhesion to the film-forming roll to be non-uniform, which leads to lowered flatness of the resultant film.

In the case of a base film for a barrier film with low barrier properties used for packaging in order to obtain proper slidability on the film-forming roll, a filler is sometimes added to the base film as a typical method for imparting irregularities to the rear surface of the base film. However, due to the irregularities occurring on the rear surface of the base film to which the filler was added, when base films are laminated on top one another for storage for example, the surface of the base film is susceptible to damage caused by the irregularities thus easily resulting in low barrier properties. Therefore, in order to use the base film for a barrier film with high barrier properties, it is necessary to provide a relatively thick (5 to 10 μm) planarized layer on the surface of the base film, which not only causes the film to be thicker but also complicates the production process. Further, the base film with an added filler has higher haze, and thus is not suitable for applications which require transparency, such as displays, organic EL illuminations, and front sheets for solar cells.

The present invention has been achieved in light of the above-described circumstances, and an object of the present invention is to provide a gas barrier film having high gas barrier properties and having excellent flatness.

### Solution to Problem

[1] A roll of a gas barrier film obtained by winding a gas barrier film having a base and a gas barrier layer in a direction orthogonal to a width of the film, in which: the gas barrier layer contains silicon atoms, oxygen atoms and carbon atoms, a carbon distribution curve, wherein:

the gas barrier layer contains silicon atoms, oxygen atoms and carbon atoms;

a carbon distribution curve with a distance from a surface of the gas barrier layer in a film thickness direction as X value and a content ratio of the carbon atoms relative to a total amount of the silicon atoms, the oxygen atoms and the carbon atoms as Y value has a maximum value and a minimum value;

a surface of the base, opposite to a side on which the gas barrier layer is disposed, has protrusions A having a height of 10 nm or more and less than 100 nm from a roughness center plane at a density of 500 to 10,000/mm², and protrusions B having a height of 100 nm or more from a roughness center plane at a density of 0 to 500/mm²;

the base has a haze of 1% or less measured in accordance with JIS K-7136; and

when a strip with a width of 20 mm including both ends in a widthwise direction of the gas barrier film and being obtained by cutting in a direction parallel to the widthwise direction of the gas barrier film is kept for 10 minutes at 25° C. and at 50% RH on a stage, and then the number of sites raised 1 mm or more from a surface of the stage is counted in a lengthwise direction of the strip, a flatness index defined as the number of sites raised 1 mm or more from the surface of the stage per total length of the strip is within a range of from 0 to 5.

[2] The roll of a gas barrier film according to [1], in which a thickness of the base is more than 25 μm and 200 μm or less.

[3] The roll of a gas barrier film according to [1] or [2], in which the base has a coating layer containing microparticles on a surface opposite to the side on which the gas barrier layer is disposed.

[4] A process for producing a gas barrier film using a plasma CVD film-forming apparatus including a vacuum chamber, a pair of film-forming rolls disposed inside the vacuum chamber and having rotation axes being approximately parallel to each other, with a magnetic field-generating member being contained therein, and a power source that provides a potential difference between the pair of film-forming rolls, a film formation surface of an elongated base wound around one of the film-forming rolls and a film formation surface of the elongated base wound around the other of the film-forming rolls face each other across film-forming space, as the elongated base is conveyed while being wound around the pair of film-forming rolls, with a wrap angle of the base wound around the film-forming rolls being 150° or more;

the process comprises: supplying a film-forming gas containing an organic silicon compound gas and oxygen gas to the film-forming space; providing a potential difference between the pair of film-forming rolls with the power source to generate discharge plasma in the film-forming space; and forming a thin film gas barrier layer containing silicon atoms, oxygen atoms and carbon atoms on the film formation surface of the base;

the base has a haze of 1% or less measured in accordance with JIS K-7136; and

a surface of the base to be in contact with the film-forming roll has protrusions A having a height of 10 nm or more and less than 100 nm from a roughness center plane at a density of 500 to 1,000/mm², and protrusions B having a height of 100 nm or more from a roughness center plane at a density of 0 to 500/mm².

[5] The process for producing a gas barrier film according to [4], in which a thickness of the base is more than 25 μm and 200 μm or less.

[6] The process for producing a gas barrier film according to [4] or [5], in which the base has a coating layer containing microparticles on a surface to be in contact with the film-forming roll.

### Advantageous Effects of Invention

According to the present invention, it is possible to provide a gas barrier film having high gas barrier properties and having excellent flatness.

### BRIEF DESCRIPTION OF DRAWINGS

FIG. 1 is a schematic view illustrating an embodiment of a gas barrier film of the present invention;

FIG. 2 is an explanatory view of a maximum value and a minimum value in a distribution curve of a specific atom;

FIG. 3 is a schematic view illustrating an example of a basic configuration of a plasma CVD film-forming apparatus used for a process for producing a gas barrier film of the present invention;

FIG. 4 is a schematic view illustrating a method of sampling strip S to be used for evaluating the flatness of a gas barrier film;

FIG. 5 is a schematic view illustrating a lengthwise cross-sectional shape of strip S in FIG. 4;

FIG. 6 is a schematic view illustrating an example of a configuration of a surface-sealing type organic EL display device;

FIG. 7 is a schematic view illustrating an example of a configuration of an organic EL element on a substrate; and

FIG. 8 is a schematic view illustrating the relationship between the concentrations of silicon atoms, oxygen atoms and carbon atoms, and the distance (nm) from the surface of a gas barrier layer, in Examples.

### DESCRIPTION OF EMBODIMENTS

1. Gas Barrier Film

A gas barrier film of the present invention includes a base, and a gas barrier layer.

Base

The base may include a resin film. Examples of resins for the resin film include polyester resins such as polyethylene terephthalate (PET), and polyethylene naphthalate (PEN); polyolefin resins such as polyethylene (PE), polypropylene (PP), and cyclic polyolefins; polyamide resins; polycarbonate resins; polystyrene resins; polyvinyl alcohol resins; saponified products of ethylene-vinyl acetate copolymers; polyacrylonitrile resins; acetal resins; and polyimide resins. Among those resins, polyester resins and polyolefin reins are preferred, and PET and PEN are more preferred, from the viewpoints of excellent heat resistance as well as linear expansion coefficient and low production cost. The resins for the resin film may be used either singly or in combination.

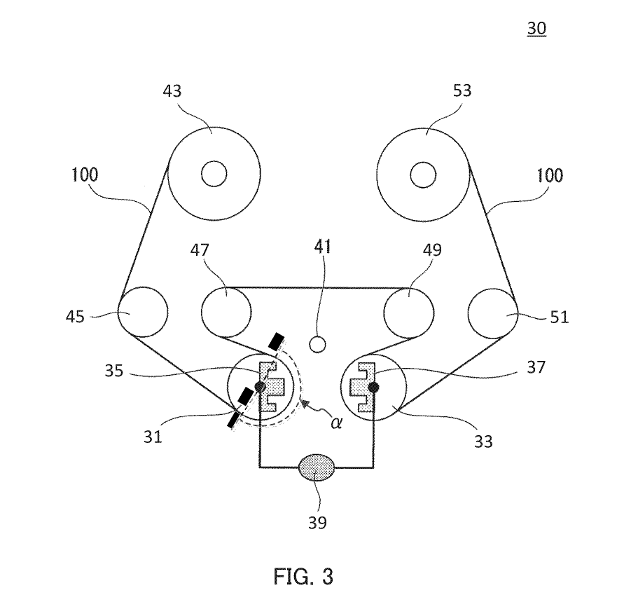

The gas barrier film of the present invention is obtained through a step of forming a gas barrier layer on a base using a film-forming apparatus illustrated in FIG. 3, as described below. However, the gas barrier film produced by the film-forming apparatus illustrated in FIG. 3 has a larger wrap angle around the film-forming roll as described above, and thus the base is considered to be less likely to slide on the film-forming roll. Thus, there has been a disadvantage in which the tension to be applied to the base becomes non-uniform, causing a wrinkle extending substantially in a lengthwise direction to easily occur on the resultant gas barrier film, which easily leads to lowered flatness.

In order to reduce such lowering of the flatness of the gas barrier film, it is effective to uniformize the tension applied to the base during film formation. In order to uniformize the tension applied to the base, it is considered to be effective to properly enhance the slidability of the base on the film-forming roll. Therefore, in the present invention, the surface properties (height and density of protrusions) of the rear surface of the base, opposite to the surface on which a gas barrier layer is disposed, are adjusted to fall within predetermined ranges.

Specifically, the rear surface of the base preferably has protrusions A having a height of 10 nm or more and less than 100 nm from a roughness center plane. The density of the protrusions A is preferably 500 to 10,000/mm², and more preferably 2,000 to 8,000/mm². There is a possibility that too low density of protrusions A may result in failure to sufficiently improve the slidability of the base on the film-forming roll, making it impossible to sufficiently uniformize the tension. On the other hand, there is a possibility that too high density of protrusions A may cause the adjacent gas barrier layer to be damaged when the base is wound into a roll.

There is a concern that, among protrusions A, protrusions A′ having a height of 50 nm or more from a roughness center plane may damage the adjacent gas barrier layer when the elongated gas barrier film is wound into a roll. Therefore, among protrusions A, the density of protrusions A′ having a height of 50 nm or more and less than 100 nm from a roughness center plane is preferably 1,000/mm² or less, and more preferably 600/mm² or less.

The rear surface of the base may further have protrusions B having a height of 100 nm or more from a roughness center plane. However, due to their relatively large height, protrusion B is likely to damage the adjacent gas barrier layer when the elongated base barrier film is wound into a roll. Therefore, the density of protrusions B is preferably 500/mm² or less, more preferably 300/mm² or less, and even more preferably 150/mm² or less.

That is, it is preferred that the density of protrusions A having a height of 10 nm or more and less than 100 nm from a roughness center plane is set at 500 to 10,000/mm², and that the density of protrusions B having a height of 100 nm or more from a roughness center plane is set at 500/mm² or less.

The density of protrusions A and B on the rear surface of the base can be measured according to the following procedure:

1) First, the surface shape of the rear surface of the base is measured using a non-contact three-dimensional surface roughness meter Wyko NT 9300 manufactured by Veeco Instruments, Inc. in PSI mode and at a measurement magnification of ×40. The area of the measurement region per measurement is set as 159.2 μm×119.3 μm, and the measurement points are 640×480 points (pixel numbers in image display).

2) The measurement data obtained in the above step 1) are converted to a color-coded height display image in a gray scale (highest point is displayed white, and lowest point is displayed black in height scale display), and inclination correction and correction for cylindrical deformation are conducted. In color-coded height display image 1 in which the highest point is set at 10 nm and the lowest point is set at 10 nm in the height scale display, a region having a height of 10 nm or more from the roughness center plane is displayed white, whereas a region having a height of less than 10 nm is displayed black. Then, the number of insular white regions per area of a measurement region (159.2 μm×119.3 μm) in the color-coded height display image 1 is counted to determine the “density (number/mm²) of protrusions having a height of 10 nm or more from the roughness center plane.” It is noted that an insular white region being in contact with four outermost peripheral sides of the measurement region is counted as a half.

3) Likewise, the measurement data obtained in the above step 1) are converted to color-coded height display image 2 in which the highest point is set at 100 nm and the lowest point is set at 100 nm in the height scale display. In the color-coded height display image 2, a region having a height of 100 nm or more from the roughness center plane is displayed white, whereas a region having a height of less than 100 nm is displayed black. Then, the number of insular white regions per area of the measurement region (159.2 μm×119.3 μm) in the color-coded height display image 2 is counted to determine the “density (number/mm²) of protrusions B having a height of 100 nm or more from the roughness center plane.”

4) Then, the “density (number/mm²) of protrusions B having a height of 100 nm or more from the roughness center plane” obtained in the above step 3) is subtracted from the “density (number/mm²) of protrusions having a height of 10 nm or more from the roughness center plane” in the above step 2) to determine the “density (number/mm²) of protrusions A having a height of 10 nm or more and less than 100 nm from the roughness center plane.”

5) Likewise, the measurement data obtained in the above step 1) are converted to color-coded height display image 3 in which the highest point is set at 50 nm and the lowest point is set at 50 nm in the height scale display. In the color-coded height display image 3, a region having a height of 50 nm or more from the roughness center plane is displayed white, whereas a region having a height of less than 50 nm is displayed black. Then, the number of insular white regions per area of the measurement region (159.2 μm×119.3 μm) in the color-coded height display image 3 is counted to determine the “density (number/mm²) of protrusions having a height of 50 nm or more from the roughness center plane.”

6) Then, the “density (number/mm²) of protrusions B having a height of 100 nm or more from the roughness center plane” obtained in the above step 3) is subtracted from the “density (number/mm²) of protrusions having a height of 50 nm or more from the roughness center plane” in the above step 5) to determine the “density (number/mm²) of protrusions A′ having a height of 50 nm or more and less than 100 nm from the roughness center plane.”

The measurement in the above step 1) is conducted using five arbitrary points on the rear surface of the base. The density of each type of protrusion is determined as an average value of five measurement values.

The height and density of the protrusions on the rear surface of the base may be adjusted by any method. For example, the rear surface of the resin film either may be subjected to roughening treatment by etching or the like, or may have a coating layer containing microparticles provided thereon.

Among those methods, from the viewpoint of easily controlling the height and density of the protrusions, it is preferred that a coating layer containing microparticles is provided on the rear surface of the resin film. That is, the base preferably has the resin film, and the coating layer provided on the rear surface thereof and containing microparticles.

Coating Layer

The coating layer contains a cured product of a curable resin (binder resin), and microparticles held by the cured product.

The curable resin for the “cured product of a curable resin” may be an organic resin or organic-inorganic composite resin having a polymerizable group or a cross-linking group.

The cross-linking group refers to a group that undergoes cross-linking reaction by photoirradiation or heat treatment. Examples of such a cross-linking group include a functional group that may undergo addition polymerization and a functional group that may become a radical. Specific examples of the functional group that may undergo addition polymerization include an ethylenic unsaturated group and a cyclic ether group such as an epoxy group/oxetanyl group; and examples of the functional group that may become a radical include a thiol group, halogen atoms, and an onium salt structure.

The organic resin is a resin obtained from a monomer, an oligomer, a polymer, and the like composed of an organic compound. The organic-inorganic composite resin may be a resin obtained from a monomer, an oligomer, a polymer, and the like of siloxane or silsesquioxane having an organic group, or a resin in which inorganic nanoparticles is composited with a resin emulsion.

The curable resin preferably contains a compound having an ethylenic unsaturated group, among those functional groups. The compound having an ethylenic unsaturated group is preferably a (meth)acrylate compound. Examples of the (meth)acrylate compound include:

monofunctional compounds such as methyl acrylate, ethyl acrylate, n-propyl acrylate, isopropyl acrylate, n-butyl acrylate, isobutyl acrylate, tert-butyl acrylate, n-pentyl acrylate, n-hexyl acrylate, 2-ethylhexyl acrylate, n-octyl acrylate, n-decyl acrylate, hydroxyethyl acrylate, hydroxypropyl acrylate, allyl acrylate, benzyl acrylate, butoxyethyl acrylate, butoxyethylene glycol acrylate, cyclohexyl acrylate, dicyclopentanyl acrylate, 2-ethylhexyl acrylate, glycerol acrylate, glycidyl acrylate, 2-hydroxyethyl acrylate, 2-hydroxypropyl acrylate, isobornyl acrylate, isodexyl acrylate, isooctyl acrylate, lauryl acrylate, 2-methoxyethyl acrylate, methoxyethylene glycol acrylate, phenoxyethyl acrylate, and stearyl acrylate; and

polyfunctional compounds, or bifunctional or higher functional compounds such as ethylene glycol diacrylate, diethylene glycol diacrylate, 1,4-butanediol diacrylate, 1,5-pentanediol diacrylate, 1,6-hexadiol diacrylate, 1,3-propanediol acrylate, 1,4-cyclohexanediol diacrylate, 2,2-dimethylolpropane diacrylate, glycerol diacrylate, tripropylene glycol diacrylate, glycerol triacrylate, trimethylolpropane triacrylate, polyoxyethyltrimethylolpropane triacrylate, pentaerythritol triacrylate, pentaerythritol tetraacrylate, ethylene oxide modified pentaerythritol triacrylate, ethylene oxide modified pentaerythritol tetraacrylate, propione oxide modified pentaerythritol triacrylate, propione oxide modified pentaerythritol tetraacrylate, triethylene glycol diacrylate, polyoxypropyltrimethylolpropane triacrylate, butyleneglycol diacrylate, 1,2,4-butanediol triacrylate, 2,2,4-trimethyl-1,3-pentadiol diacrylate, diallyl fumarate, 1,10-decanediol dimethyl acrylate, and pentaerythritol hexaacrylate. The above-mentioned (meth)acrylate compound may be a monomer, oligomer or polymer, or a mixture thereof.

The microparticles may be any of inorganic microparticles, organic microparticles and organic-inorganic composite microparticles. Among these microparticles, inorganic microparticles are preferred due to their excellent abrasion resistance.

An inorganic compound constituting the inorganic microparticles is preferably a metal oxide due to its transparency. Examples of the metal oxide include SiO₂, Al₂O₃, TiO₂, ZrO₂, ZnO, SnO₂, In₂O₃, BaO, SrO, CaO, MgO, VO₂, V₂O₅, CrO₂, MoO₂, MoO₃, MnO₂, Mn₂O₃, WO₃, LiMn₂O₄, Cd₂SnO₄, CdIn₂O₄, Zn₂SnO₄, ZnSnO₃, Zn₂In₂O₅, Cd₂SnO₄, CdIn₂O₄, Zn₂SnO₄, ZnSnO₃, and Zn₂In₂O₅. The microparticles contained in the coating layer may be used either singly or in combination.

The height of protrusions on the surface of the coating layer may be adjusted for example by the average particle diameter of the microparticles; and the density of the protrusions may be adjusted for example by the content of the microparticles.

It is sufficient for the average particle diameter of the microparticles to be set such that at least the height of the protrusions present on the surface of the coating layer is set within the range of 10 nm or more and less than 100 nm; the average particle diameter of the microparticles can be set within the range of, for example, 10 nm to 2 μm, preferably 30 nm to 300 nm, and more preferably 40 nm to 200 nm. When the average particle diameter of the microparticles is less than 10 nm, protrusions may not be formed. On the other hand, when the average particle diameter of the microparticles is more than 2 μm, the height of the protrusions from the roughness center plane becomes too high, and thus may not be adjusted to less than 100 nm

It is also sufficient for the content of the microparticles to be set such that the density of the predetermined protrusions is within a predetermined range; the content of the microparticles can be set, for example, within the range of from 0.001 to 10% by mass with respect to the total weight of the coating layer, and preferably within the range of from 0.01 to 3% by mass. When the content of the microparticles is less than 0.001% by mass, the density of protrusions A may be too low. On the other hand, when the content of the microparticles is more than 10% by mass, the density of protrusions A may be too high, resulting in possible damage of the adjacent gas barrier layer when the gas barrier film is wound in a roll.

The coating layer may further contain other components, as necessary.

The thickness of the coating layer is not particularly limited, and may be set such that the coating layer sufficiently holds the microparticles and prevents them from falling, and that the height and density of the protrusions on the surface of the coating layer can be adjusted. The thickness of the coating layer can be set at, for example, about 0.01 to 5 μm, and preferably 0.05 to 1 μm.

Such a coating layer may be formed through the steps of: applying a coating layer resin composition containing the above-mentioned curable resin, microparticles, and, as necessary, a polymerization initiator or a cross-liking agent; and then subjecting the resultant applied layer to photoirradiation or heat treatment to cure the curable resin in the applied layer.

The inorganic microparticles may be included in the coating layer resin composition as a dispersion liquid in which the inorganic microparticles are dispersed in a solvent as primary particles. The dispersion liquid of the inorganic microparticles may be prepared according to methods set forth in recent treatises, or alternatively may be commercially available products. Examples of the commercially available products include various metal oxide dispersion liquids such as Snow Tex series and Organosilica Sol manufactured by Nissan Chemical Industries, Ltd.; NANOBYK series manufactured by BYK Japan Co., Ltd., and NanoDur manufactured by Nanophase Technologies Corporation. These inorganic microparticles may be subjected to surface treatment.

The coating layer resin composition may further contain a solvent in which the curable resin is dispersed or dissolved, as necessary. Examples of such a solvent include methyl isobutyl ketone and propylene glycol monomethyl ether.

It is sufficient for the coating amount of the coating layer resin composition to be set such that the coating layer prevents fall of the microparticles, and that the height of the protrusions on the surface of the coating layer is easily adjusted, as described above; the coating amount of the coating layer resin composition can be set at, for example, 0.05 to 5 g/m², and preferably 0.1 to 3 g/m². When the coating amount is less than 0.05 g/m², the coating layer cannot hold microparticles sufficiently, which may cause the microparticles to fall. On the other hand, when the coating amount is more than 5 g/m², there is often no advantage in the performance.

The base may further contain additional layer(s) between the resin film and the coating layer, as necessary.

The surface of the base on which the gas bather layer is disposed may be subjected to surface activation treatment, in order to enhance the adhesion to the gas barrier layer to be described hereinafter. Examples of such surface activation treatment include corona treatment, plasma treatment, and flame treatment.

In order to achieve mechanical strength enough to tolerate the tension during conveying, the thickness of the base is preferably 5 μm or more; in order to use the gas barrier film as a transparent substrate (or sealing substrate) for a display device, the thickness of the base constituting the gas barrier film is preferably more than 25 μm, more preferably 30 μm or more, and even more preferably 50 μm or more. On the other hand, in order to secure the stability of plasma discharge, the thickness of the base is preferably 500 μm or less, and more preferably 200 μm or less.

The haze of the base measured in accordance with JIS K-7136 is 1% or less, preferably 0.8% or less, and more preferably 0.5% or less. A gas barrier film having such a low haze is suitable as a transparent substrate (or sealing substrate) for a display device, for example. Specifically, when the gas barrier film of the present invention is used for the sealing substrate of a top emission organic EL display device, it may be possible to suppress a reduction in the out-coupling efficiency of an organic EL element. The measurement of haze can be conducted using a commercially available haze meter (turbidimeter) (e.g., model: NDH 2000, manufactured by Nippon Denshoku Industries Co., Ltd.) under conditions of 23° C. and 55% RH.

Gas Barrier Layer

The gas barrier layer is a thin film provided on one surface of the base and containing silicon atoms, oxygen atoms and carbon atoms. The gas barrier layer may be formed using the film-forming apparatus illustrated in FIG. 3 to be described hereinafter.

A carbon distribution curve with the distance from the surface of the gas barrier layer in the film thickness direction as X value (unit: nm), and the ratio of the content of carbon atoms (content ratio of carbon atoms) to the total amount of silicon atoms, oxygen atoms and carbon atoms in the gas barrier layer as Yc value (unit:at %), is preferably substantially continuous.

The distribution curve of carbon in the gas barrier layer preferably has at least one extreme value, more preferably has at least two extreme values, and even more preferably has at least three extreme values, because the gas barrier properties are excellent even when the film is bent.

The “extreme value” means a maximum value or a minimum value of the content ratio of a specific atom (Y value) relative to the distance from the surface of the gas barrier layer in the film thickness direction (X value).

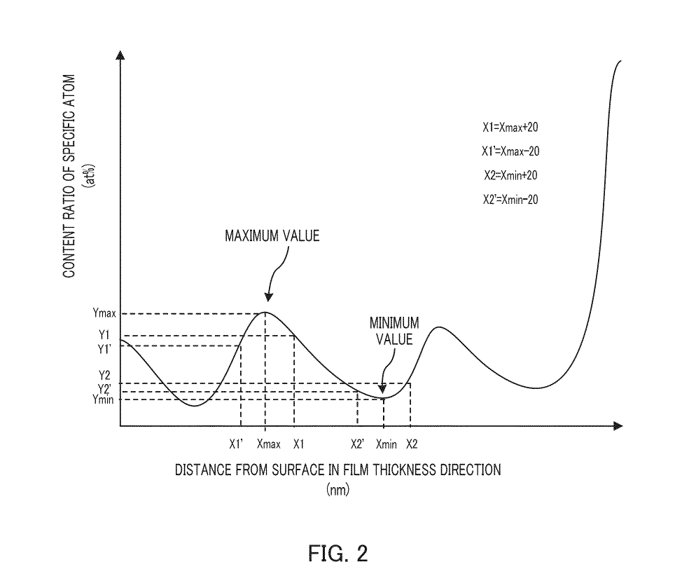

FIG. 2 is an explanatory view of a maximum value and a minimum value in the distribution curve of a specific atom. As illustrated in FIG. 2, the “maximum value” is i) a point at which the content ratio of the specific atom (Y value) changes from increase to decrease in association with the sequential change of the distance from the surface of the gas barrier layer in the film thickness direction (X value), and ii) a point at which |Y1−Ymax| and |Y1′−Ymax| are 3 at % or more, when the X value of that point is set as Xmax and the Y value thereof is set as Ymax; the X value and the Y value at a point shifted +20 nm from that point in the film thickness direction are set respectively as X1 and Y1; and the X value and the Y value at a point shifted −20 nm from that point in the film thickness direction are set respectively as X1′ and Y1′.

The “minimum value” is i) a point at which the content ratio of the specific atom (Y value) changes from decrease to increase in association with the sequential change of the distance from the surface of the gas barrier layer in the film thickness direction (X value), and ii) a point at which |Y2−Ymin| and |Y2′−Ymin| are 3 at % or more, when the X value of that point is set as Xmin and the Y value thereof is set as Ymin; the X value and the Y value at a point shifted +20 nm from that point in the film thickness direction are set respectively as X2 and Y2, and the X value and the Y value at a point shifted −20 nm from that point in the film thickness direction are set respectively as X2′ and Y2′.

The distribution curve of carbon in the gas barrier layer preferably has at least a maximum value and a minimum value. The absolute value of the difference between the greatest value of the maximum value and the smallest value of the minimum value is preferably 5 at % or more, more preferably 6 at % or more, and even more preferably 7 at % or more, because the gas barrier properties are excellent even when the film is bent.

In the distribution curve of carbon in the gas barrier layer, the content ratio of carbon atoms (Yc value) is preferably 1 at % or more, and more preferably 3 at % or more, throughout the entire region in the film thickness direction of the layer. When the gas barrier layer has a region which contains no or almost no carbon atoms, the gas barrier properties may not be sufficient when the film is bent. The upper limit of the content ratio of carbon atoms (Yc value) may be set at 67 at % or less throughout the entire region of the film thickness of the gas barrier film.

The oxygen distribution curve with the distance from the surface of the gas barrier layer in the film thickness direction as X value, and the ratio of the content of oxygen atoms (content ratio of oxygen atoms) to the total amount of silicon atoms, oxygen atoms and carbon atoms in the gas barrier layer as Yo value also preferably has at least one extreme value, more preferably has at least two extreme values, and even more preferably has at least three extreme values, as with the carbon distribution curve described above. When the oxygen distribution curve does not have an extreme value, the gas barrier properties tend to be lowered even when the film is bent.

When the oxygen distribution curve has at least three extreme values, the absolute value of the difference between the X value of one extreme value and the X value of another extreme value adjacent thereto is preferably 200 nm or less, and more preferably 100 nm or less.

The absolute value of the difference between the maximum value and the minimum value of the content ratio of oxygen atoms (Yo value) in the distribution curve of oxygen in the gas barrier layer is preferably 5 at % or more, more preferably 6 at % or more, and even more preferably 7 at % or more. When the difference of the absolute value in the content ratio of oxygen atoms is too small, the gas barrier properties tend to be lowered when the film is bent.

In the silicon distribution curve with the distance from the surface of the gas barrier layer in the film thickness direction as X value and the ratio of the content of silicon atoms (content ratio of silicon atoms) to the total amount of silicon atoms, oxygen atoms and carbon atoms in this layer as Y_{Si} value, the absolute value of the difference between the maximum value and the minimum value of the Y_{Si} value is preferably 5 at % or less, more preferably less than 4 at %, and even more preferably less than 3 at %. When the absolute value of the difference between the maximum value and the minimum value of the Y_{Si} value exceeds the upper limit, the gas barrier properties of the film tend to be lowered.

In a region of 90% or more, preferably 95% or more, and more preferably 100% of the film thickness of the gas barrier layer in the silicon distribution curve, the content ratio of silicon atoms is preferably 30 at % or more and 37 at % or less. The content ratio of silicon atoms being within that range allows the gas barrier properties to be more excellent when the film is bent.

The ratio of the total amount of oxygen atoms and carbon atoms to the content of silicon atoms in the gas barrier layer is preferably more than 1.8 and 2.2 or less. The ratio of the total amount of oxygen atoms and carbon atoms being within the above-mentioned range allows the gas barrier properties to be more excellent when the film is bent.

In a region of 90% or more, preferably 95% or more, and more preferably 100% of the film thickness of the gas barrier layer, the content ratio of silicon atoms, the content ratio of oxygen atoms and the content ratio of carbon atoms preferably satisfy the following formula (1) or (2), to thereby allow the gas barrier properties of the film to be more excellent.

(content ratio of oxygen atoms)>(content ratio of silicon atoms)>(content ratio of carbon atoms) (1)

(content ratio of carbon atoms)>(content ratio of silicon atoms)>(content ratio of oxygen atoms) (2)

When the gas barrier layer satisfies the relationship of the above formula (1), the content ratio of silicon atoms in the gas barrier layer (amount of silicon atoms/(amount of silicon atoms+amount of oxygen atoms+amount of carbon atoms)) is preferably 25 to 45 at %, and more preferably 30 to 40 at %. The content ratio of oxygen atoms (amount of oxygen atoms/(amount of silicon atoms+amount of oxygen atoms+amount of carbon atoms)) is preferably 33 to 67 at %, and more preferably 45 to 67 at %. The content ratio of carbon atoms (amount of carbon atoms/(amount of silicon atoms+amount of oxygen atoms+amount of carbon atoms)) is preferably 3 to 33 at %, and more preferably 3 to 25 at %.

When the gas barrier layer satisfies the relationship of the above formula (2), the content ratio of silicon atoms (amount of silicon atoms/(amount of silicon atoms+amount of oxygen atoms+amount of carbon atoms)) is preferably 25 to 45 at %, and more preferably 30 to 40 at %. The content ratio of oxygen atoms (amount of oxygen atoms/(amount of silicon atoms+amount of oxygen atoms+amount of carbon atoms)) is preferably 1 to 33 at %, and more preferably 10 to 27 at %. The content ratio of carbon atoms (amount of carbon atoms/(amount of silicon atoms+amount of oxygen atoms+amount of carbon atoms)) is preferably 33 to 66 at %, and more preferably 40 to 57 at %.

The silicon distribution curve, the oxygen distribution curve and the carbon distribution curve can be obtained by XPS depth profile measurement in which while etching the surface of a sample of the gas barrier film by sputtering, the surface composition in the exposed sample is measured by X-ray photoelectron spectroscopy (XPS).

The sputtering method is preferably an ion sputtering method using a noble gas such as argon (Ar⁺) as etching ion species. The etching rate may be 0.05 nm/sec (value converted for SiO₂ thermal oxide film).

The distribution curve obtained by the XPS depth profile measurement may for example be a distribution curve with the content ratio (unit:at %) of each atom as the ordinate and the etching time (sputter time) as the abscissa. It is possible to calculate the distance from the surface of the gas barrier layer in the film thickness direction from the relationship between etching rate and etching time. Thus, it becomes possible to obtain a distribution curve with the content ratio (unit:at %) of each atom as the ordinate and the distance (unit: nm) from the surface of the gas barrier layer in the film thickness direction as the abscissa.

The carbon atom and the silicon atom contained in the gas barrier layer are preferably bound directly, from the viewpoint of enhancing the gas barrier properties.

The thickness of the gas barrier layer is preferably within a range of from 5 to 3,000 nm, more preferably from 10 to 2,000 nm, and even more preferably from 100 to 1,000 nm. Too small thickness of the gas barrier layer is unlikely to allow sufficient barrier properties to oxygen gas or steam to be obtained. On the other hand, too large thickness of the gas barrier layer is likely to lower the gas barrier properties due to the bending of the film.

Such a gas barrier layer may be formed preferably by plasma chemical vapor deposition.

The gas barrier film may further contain one or more other thin film layers, as necessary. The one or more other thin film layers may be disposed either on a surface of the base on which the gas barrier layer is formed, or on a surface opposite to that surface (i.e., rear surface). The thin film layers may have the same or different compositions. The one or more other thin film layers do not necessarily need to have gas barrier properties.

When the gas barrier film has one or more other thin film layers, the total value of the thickness of the gas barrier layer and other thin film layer(s) is typically within a range of from 10 to 10,000 nm, preferably from 10 to 5,000 nm, more preferably from 100 to 3,000 nm, and even more preferably from 200 to 2,000 nm. When the total value of the thickness of the gas barrier layer and the thin film layer(s) is too large, the gas barrier properties may be likely to be lowered due to the bending of the film.

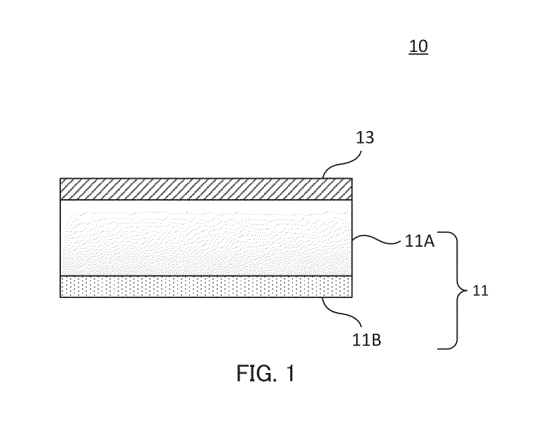

FIG. 1 is a schematic view illustrating an embodiment of a gas barrier film of the present invention. As illustrated in FIG. 1, gas barrier film 10 includes base 11 having resin film 11A and coating layer 11B provided on the rear surface of resin film 11A, and gas barrier layer 13.

The thickness of the gas barrier film may be set at about 12 to 300 μm, for example, when the gas barrier film is used as a sealing substrate for an electronic device.

The gas barrier film is required to have a certain or higher degree of transparency when used as transparent substrate or a protective film for an organic EL display device or a liquid crystal display device, as described below. Therefore, the visible light transmittance of the gas barrier film is preferably 90% or more, and more preferably 93% or more. The visible light transmittance of the gas barrier film can be measured using a commercially available haze meter (turbidimeter) (e.g., model: NDH 2000, manufactured by Nippon Denshoku Industries Co., Ltd.). The haze of the gas barrier film measured in accordance with JIS K-7136 is preferably 1% or less, and more preferably 0.5% or less.

Thus, in the present invention, proper irregularities may be imparted only on the rear surface of the gas barrier film. Therefore, excellent slidability may be imparted on the rear surface of the film without lowering the barrier properties as a result of the formation of unnecessary irregularities on the surface of the film or without increasing the haze of the film.

2. Process for Producing Gas Bather Film

A gas bather film of the present invention may be produced through the step of forming a gas barrier layer on the base using plasma chemical vapor deposition (plasma CVD method).

FIG. 3 is a schematic view illustrating an example of a basic configuration of a plasma CVD film-forming apparatus used for a process for producing a gas barrier film of the present invention. As illustrated in FIG. 3, plasma CVD film-forming apparatus 30 includes a vacuum chamber (not illustrated), a pair of film-forming rolls 31 and 33 disposed inside the vacuum chamber, magnetic field generators 35 and 37 provided inside the film-forming rolls, power source 39 that provides a potential difference between the pair of film-forming rolls, and gas supply tube 41 that supplies a gas between the pair of film-forming rolls. Base 100 with elongated shape is configured to be conveyed by being wound around feeding roll 43, conveying roll 45, film-forming roll 31, conveying rolls 47 and 49, film-forming roll 33, conveying roll 51, and winding roll 53.

Film-forming rolls 31 and 33 are disposed to face each other such that their rotation axes are approximately parallel to each other. The space formed between the pair of film-forming rolls 31 and 33 constitutes a film-forming space.

The pair of film-forming rolls 31 and 33 is typically composed of a metal material, and may not only support elongated base 100, but also function as electrodes across which a potential differential is provided by power source 39. The roll diameters of the pair of film-forming rolls 31 and 33 are preferably the same for forming a thin film efficiently. The roll diameters of the pair of film-forming rolls 31 and 33 can be set at about 5 to 100 cm, and preferably about 10 to 30 cm, from the viewpoint of discharging conditions and the space for the chamber, for example.

The pair of film-forming rolls 31 and 33 has therein magnetic field generators 35 and 37, respectively. Each of magnetic field generators 35 and 37 is a magnetic field generating mechanism composed of a permanent magnet, and may be composed, for example, of a center magnet, an outer peripheral magnet surrounding the center magnet, and a magnetic field-short-circuiting member connecting the center magnet and the outer peripheral magnet.

Power source 39 is configured to generate plasma between the pair of film-forming rolls 31 and 33 by providing a potential difference between the pair of film-forming rolls 31 and 33. Power source 39 is preferably a power source that may alternately invert the polarities of the pair of film-forming rolls 31 and 33 (e.g., alternating source), since it is easy to conduct plasma CVD more efficiently. Gas supply tube 41 is configured to be able to supply a film-forming gas for forming the gas barrier layer to the film-forming space.

In such film-forming apparatus 30, a film-forming surface of base 100 wound around film-forming roll 31 and a film-forming surface of base 100 wound around film-forming roll 33 face each other across the film-forming space. Wrap angle α of base 100 wound around each of film-forming rolls 31 and 33 can be set at 120° to 270°, and may be preferably set at 150° to 210°, although the wrap angle α is not particularly limited.

While conveying base 100, a film-forming gas containing an organic silicon compound gas and oxygen gas is supplied to the film-forming space from gas supply tube 41. Power source 39 provides a potential difference between the pair of film-forming rolls 31 and 33 to generate discharge plasma in the film-forming space, thereby simultaneously forming a thin film gas barrier layer containing silicon atoms, oxygen atoms and carbon atoms on the surface of base 100 conveyed on the pair of film-forming rolls 31 and 33.

It is sufficient for the width of base 100 to be set depending on applications; the width of base 100 can be set at about 200 to 2,000 mm, and preferably may be set at 300 to 1,500 mm.

The film-forming gas to be supplied to the film-forming space contains a source gas from which the gas barrier layer is formed, and, as necessary, may further contain a reactant gas that forms a compound by reacting with the source gas, or an auxiliary gas that facilitates plasma generation or enhances the film quality but is not contained in the resultant film.

The source gas contained in the film-forming gas may be selected depending on the composition of the gas barrier layer. Examples of the source gas include an organic silicon compound containing silicon. Examples of the organic silicon compound include hexamethyldisiloxane, 1,1,3,3-tetramethyldisiloxane, vinyltrimethylsilane, methyltrimethylsilane, hexamethyldisilane, methylsilane, dimethylsilane, trimethylsilane, diethylsilane, propylsilane, phenylsilane, vinyltriethoxysilane, vinyltrimethoxysilane, tetramethoxysilane, tetraethoxysilane, phenyltrimethoxysilane, methyltriethoxysilane, and octamethylcyclotetrasiloxane. Among these compounds, in terms of excellent handleability thereof as well as excellent gas barrier properties of the resultant film, hexamethyldisiloxane and 1,1,3,3-tetramethyldisiloxane are preferred. The organic silicon compounds may be used either singly or in combination. The source gas may further contain monosilane, in addition to the above-mentioned organic silicon compounds.

The reactant gas that may be contained in the film-forming gas may be a gas that forms an inorganic compound such as an oxide or a nitride by reaction with the source gas. Examples of the reactant gas for forming an oxide include oxygen and ozone. Examples of the reactant gas for forming a nitride include nitrogen and ammonia. The reactant gases may be used either singly or in combination. For example, when forming a thin film containing an oxynitride, the film-forming gas may contain a reactant gas for forming an oxide and a reactant gas for forming a nitride.

The film-forming gas may further contain, as necessary, a carrier gas for facilitating the supply of the source gas into the vacuum chamber, or a discharging gas for facilitating the generation of plasma discharge. Examples of the carrier gas or the discharging gas include noble gases such as helium, argon, neon and xenon gases, and hydrogen gas.

In the film-forming gas containing the source gas and the reactant gas, the molar amount of the reactant gas is preferably not too much relative to the theoretically necessary amount for complete reaction of the source gas with the reactant gas. Too much molar amount of the reactant gas may make it difficult to obtain a gas barrier layer that satisfies the above-described properties. For example, when the film-forming gas contains hexamethyldisiloxane (organic silicon compound) as a source gas and oxygen (O₂) as a reactant gas, the molar amount of oxygen in the film-forming gas is preferably not more than than the theoretical amount necessary for completely oxidizing the total amount of hexamethyldisiloxane.

By adjusting the composition of the film-forming gas in the manner as described above, carbon atoms or hydrogen atoms in hexamethyldisiloxane, which are not completely oxidized, are introduced into the resultant gas barrier layer, to easily allow the gas barrier layer that satisfies the above-described properties to be obtained.

On the other hand, too small molar amount of oxygen relative to the molar amount of hexamethyldisiloxane in the film-forming gas causes carbon atoms or hydrogen atoms which are not oxidized to be introduced excessively into the gas barrier layer, thus lowering the transparency of the resultant gas barrier layer, and low transparency may not be suitable for applications that require transparency. From such a point of view, the lower limit of the molar amount of oxygen relative to the molar amount of hexamethyldisiloxane in the film-forming gas is preferably an amount more than 0.1 times as much as the molar amount of hexamethyldisiloxane, and more preferably an amount more than 0.5 times as much as the molar amount thereof.

The power to be applied by power source 39 is set at, for example, 100 W to 10 kW; and the frequency of the alternating current may be set at 50 Hz to 500 kHz.

The pressure inside the vacuum chamber (degree of vacuum) is appropriately set depending on the type of the source gas, and may be set at, for example, a range of from 0.1 to 50 Pa.

In the plasma CVD method, the power to be applied between film-forming rolls 31 and 33 is set depending on, for example, the type of the source gas or the pressure inside the vacuum chamber, and may be set at, for example, a range of from 0.1 to 10 kW. Too low application power tends to cause the resultant gas barrier layer to contain particles. On the other hand, too high application power causes too much amount of heat to be generated during film formation, thus increasing the temperature of the surface of base 100 during film formation, which may result in possible occurrence of a wrinkle due to the heat, or possible melting due to the heat during film formation.

The conveying speed (line speed) of base 100 may be appropriately set depending on, for example, the type of the source gas or the pressure inside the vacuum chamber, and can be set at, for example, a range of from 0.1 to 100 m/min, and preferably at a range of from 0.5 to 20 m/min Too low line speed tends to cause a wrinkle to occur on the base due to heat, whereas too high line speed tends to cause the thickness of the thin film layer that is formed to be small.

As described above, in the present invention, a surface of base 100 opposite to a film-forming surface (i.e., rear surface of base 100) has surface properties (height and density of protrusions) being adjusted to a predetermined range, thereby allowing the slidability of base 100 on film-forming rolls 31 and 33 to be excellent in spite of a large wrap angle of base 100 around film-forming rolls 31 and 33. Thus, the tension of base 100 becomes uniform, making it possible to obtain a gas barrier film having high flatness, with a wrinkle or the like extending in a substantially lengthwise direction being suppressed.

The flatness index of the gas barrier film measured by the following method is preferably 0 to 5, more preferably 0 to 3, and even more preferably 0 to 2.

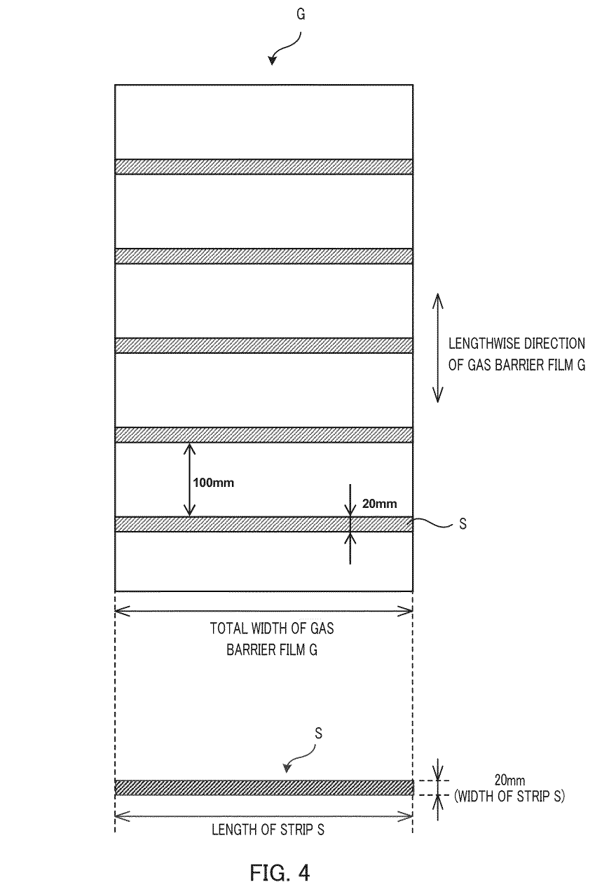

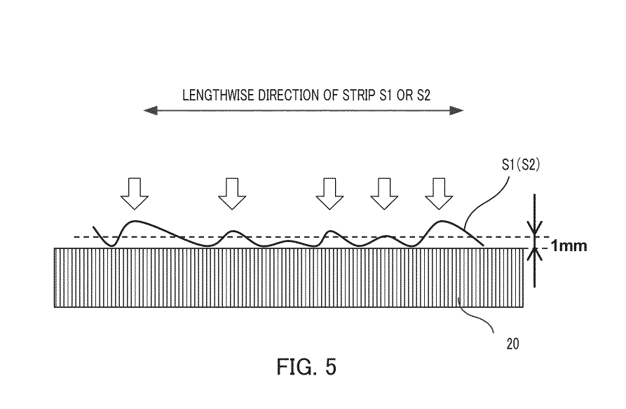

The flatness of the gas barrier film can be measured by the method set forth below. FIG. 4 is a schematic view illustrating a method of sampling strip S to be used for evaluating the flatness of the gas barrier film; and FIG. 5 is a schematic view illustrating a lengthwise cross-sectional shape of strip S in FIG. 4.

1) First, as illustrated in FIG. 4, strip S including both ends in the widthwise direction of elongated gas barrier film G and being parallel to the width of the gas barrier film is cut out. As illustrated in FIG. 4, the width of strip S is set at 20 mm; and the length of strip S may be the entire width of the gas barrier film. Five pieces of strip S are cut out for every 100 mm in the lengthwise direction of gas barrier film G.

2) Next, as illustrated in FIG. 5, the resultant strip S is disposed on stage 20 with the gas barrier layer upward. Then, after the elapse of 10 minutes from the time when strip S is left at rest at 25° C. and at 50% RH, sites at which strip S is raised 1 mm or more (arrow parts) from the surface of stage 20 are counted along the lengthwise direction of strip S. Specifically, the number of the raised sites throughout the entire length in the lengthwise direction of strip S when being visually observed from one side a in the widthwise direction of strip S (number ca) is counted. It should be noted that raised sites at both ends (in the lengthwise direction of strip S), among a plurality of raised sites, are not counted. Likewise, the number of raised sites when being observed from the other side b in the widthwise direction of strip S (number cb) is also counted. Then, the larger value of the resultant numbers ca and cb is set as the “number c of raised sites.” A similar measurement is also conducted for 5 pieces of strip S.

3) The average value of the numbers of the raised sites c of the 5 pieces of strip S, obtained in the above step 2), is defined as “flatness index.”

3. Electronic Device

The gas barrier film of the present invention may be used for example as a transparent substrate (or a sealing substrate) for an electronic device such as an organic EL display device or a liquid crystal display device that requires gas barrier properties. The gas barrier film of the present invention has flexibility, and thus is used preferably as a transparent substrate (or a sealing substrate) for a flexible electronic device such as a flexible organic EL display device or a liquid crystal display device; and more preferably as a transparent substrate (or a sealing substrate) for a surface-sealing type flexible organic EL display device.

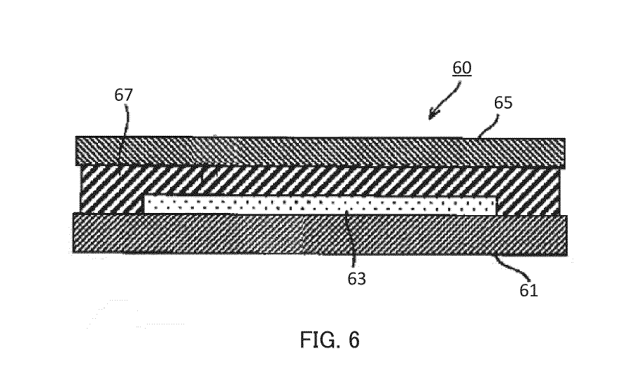

FIG. 6 is a schematic view illustrating an example of the configuration of a surface-sealing type organic EL display device. As illustrated in FIG. 6, surface-sealing type organic EL display device 60 includes substrate 61, organic EL element 63 provided on substrate 61, sealing substrate (transparent substrate) 65 that seals organic EL element 63, and sealing resin layer 67 filled between substrate 63 and sealing substrate 65. The gas barrier film of the present invention can be used preferably as sealing substrate 65.

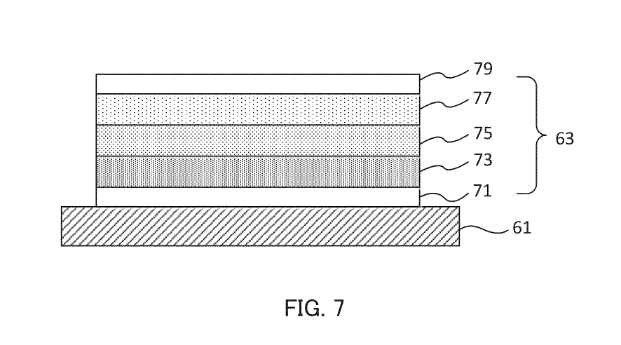

FIG. 7 is a schematic view illustrating an example of the configuration of organic EL element 63 provided on substrate 61. As illustrated in FIG. 7, organic EL element 63 includes, sequentially, lower electrode 71 as an anode electrode, hole transport layer 73, emitter layer 75, electron transport layer 77, and upper electrode as a cathode electrode. Such a configuration allows light emitted by recombination of electrons and holes, at emitter layer 75, injected from lower electrode 71 and upper electrode 79 to be out-coupled from the sealing substrate 65 (see FIG. 6) side.

Such a surface-sealing type organic EL display device may be manufactured, for example, through the steps of: 1) forming organic EL element 63 on substrate 61 to produce an element member L; 2) supplying uncured resin material M onto the element member L to cover the entire organic EL element 63 to form sealing resin layer 67; 3) placing and pressing sealing substrate 65 held substantially horizontal on and against sealing resin layer 67 to bond sealing substrate 65 to sealing resin layer 67; and 4) curing sealing resin layer 67.

Gas barrier film G of the present invention used as sealing substrate 65 has excellent flatness. Therefore, it is possible to suppress the occurrence of warpage or a wrinkle on the gas barrier film, in the step 3).

### EXAMPLES

Hereinafter, the present invention will be described in more detail with reference to Examples which however shall not be construed as limiting the scope of the present invention.

### 1. Production of Base Film

### 1) Base Film 0

As base film 0, a polyethylene naphthalate film (manufactured by Teijin DuPont Films Ltd., Q65FWA) having a width of 350 mm and a thickness of 100 μm was provided.

### 2) Base Film 1

First, as a coating layer resin composition A, a UV-curable organic/inorganic hybrid hard coat material OPSTAR Z7535 manufactured by JSR Corporation appropriately diluted with propylene glycol monomethyl ether was provided.

Next, the above coating layer resin composition A was applied to a surface of the polyethylene naphthalate film (manufactured by Teijin DuPont Films Ltd., Q65FWA) having a thickness of 100 μm, opposite to the film-forming surface, (i.e., rear surface), so as to have a dried coating amount of 0.3 g/m² using a known extrusion coater on a roll-to-roll coating line. The film on which the coating layer resin composition A had been applied was allowed to pass through a drying zone at 80° C. for 3 minutes. Then, the resultant coated layer of the coating layer resin composition A was irradiated with ultraviolet radiation at an irradiation energy dose of 1.0 J/cm² in an air atmosphere using a high-pressure mercury lamp to cure the coated layer, thereby affording base film 1 having a coating layer on the rear surface.

### 3) Base Films 2 to 10

### Preparation of Coating Layer Resin Compositions B to J

The UV-curable organic/inorganic hybrid hard coat material OPSTAR Z7535 manufactured by JSR Corporation were mixed and dispersed with silica microparticles having the average particle diameters listed in Table 1 set forth below such that the content ratios of the microparticles in the solid content had the values as shown in Table 1 set forth below, to afford coating layer resin compositions B to J.

Base films 2 to 10 having a coating layer were obtained similarly to the above-described production of base film 1, by applying the resultant coating layer resin compositions B to J to a surface of the polyethylene naphthalate film (manufactured by Teijin DuPont Films Ltd., Q65FWA) having a thickness of 100 μm, opposite to the film-forming surface, (i.e., rear surface), using a known extrusion coater, except that the dried coating amounts of the coating layer resin compositions B to J were listed in Table 1 set forth below.

The surface conditions (specifically, height and density of protrusions) of the rear surfaces of the resultant base films 0 to 10 were measured according to the following methods.

[Height and Density of Protrusions]

1) First, the surface shape of the rear surface (the surface of the coating layer in the base films 1 to 10) of the resultant base film was measured using a non-contact three-dimensional surface roughness meter Wyko NT 9300 manufactured by Veeco Instruments, Inc. at PSI mode and at a measurement magnification of ×40. The measurement range per measurement was set as 159.2 μm×119.3 μm, and the measurement points were 640×480 points (pixel numbers in image display).

2) Next, the obtained measurement data were converted to a color-coded height display image in a gray scale (highest point is white, and lowest point is black in height scale display), and inclination correction and correction of cylindrical deformation were conducted. In color-coded height display image 1 in which the highest point is set at 10 μm and the lowest point is set at 10 μm in the height scale display, a region having a height of 10 μm or more from the roughness center plane is displayed white, whereas a region having a height of less than 10 μm is displayed black. At that time, the protrusions on the rear surface of the base film are displayed as insular white regions. Therefore, the number of the insular white regions per area of 159.2 μm×119.3 μm in the color-coded height display image 1 was counted to calculate the “density (number/mm²) of protrusions having a height of 10 nm or more from the roughness center plane.” It is noted that an insular white region being in contact with four outermost peripheral sides of the measurement region was counted as a half.

3) Likewise, in color-coded height display image 2 in which the highest point is set at 100 nm and the lowest point is set at 100 nm in the height scale display, a region having a height of 100 nm or more from the roughness center plane is displayed white, whereas a region having a height of less than 100 nm is displayed black. The number of the insular white regions per area of 159.2 μm×119.3 μm at that time was counted to calculate the “density (number/mm²) of protrusions B having a height of 100 μm or more from the roughness center plane.”

4) Then, the “density (number/mm²) of protrusions B having a height of 100 nm or more from the roughness center plane” obtained in the above step 3) was subtracted from the “density (number/mm²) of protrusions having a height of 10 nm or more from the roughness center plane” in the above step 2) to determine the “density (number/mm²) of protrusions A having a height of 10 nm or more and less than 100 nm from the roughness center plane.” It should be noted, however, that there are some protrusions that branch midway in the height direction. There is a case, for example, in which such protrusions may be observed as “a single insular white region” in the color-coded height display image 1, while such protrusions may be observed as “a plurality of insular white regions” in the color-coded height display image 2. In that case, in the calculation of the density of the protrusions A, the number of the insular white regions in the color-coded height display image 2 was counted as “1.”

5) Likewise, in the color-coded height display image 3 in which the highest point is set at 50 nm and the lowest point is set at 50 nm in the height scale display, a region having a height of 50 nm or more from the roughness center plane is displayed white, whereas a region having a height of less than 50 nm is displayed black. The number of the insular white regions per area of 159.2 μm×119.3 μm at that time was counted to calculate the “density (number/mm²) of protrusions having a height of 50 nm or more from the roughness center plane.”

6) Then, the “density (number/mm²) of protrusions B having a height of 100 nm or more from the roughness center plane” obtained in the above step 3) was subtracted from the “density (number/mm²) of protrusions having a height of 50 nm or more from the roughness center plane” in the above step 5) to determine the “density (number/mm²) of protrusions A′ having a height of 50 nm or more and less than 100 nm from the roughness center plane.”

7) The measurement of the above step 1) was conducted at five arbitrary points on the rear surface of the base film. The density of each type of protrusions was determined as an average value of five measurement values.

[Haze]

The haze of the resultant base film was measured using a haze meter (turbidimeter) (model: NDH 2000, manufactured by Nippon Denshoku Industries Co., Ltd.) under conditions of 23° C. and 55% RH in accordance with JIS K-7136.

The evaluation results of the base films 0 to 10 are shown in Table 1.

TABLE 1

| | Rear Surface Coating | | | | | | | |
|---|---|---|---|---|---|---|---|---|
| | | Silica Particles | | | | | | |
| | | Average | Content | | Density of Rear Surface Protrusions | | | |
| | | Particle | Ratio | Coating | (number/mm²) | | | |
| Base Film | | Diameter | (% by | Amount | Protrusions A | | Protrusions B | |
| No. | Type | (μm) | mass) | (g/m²) | 10 to 100 nm | 50 to 100 nm | 100 nm or more | Haze |
| 0 | None | | | | 300 | 110 | 160 | 0.4 |
| 1 | A | | | 0.3 | 160 | 0 | 0 | 0.4 |
| 2 | B | 0.3 | 0.05 | 0.3 | 2000 | 160 | 0 | 0.4 |
| 3 | C | 0.3 | 0.1 | 0.3 | 4110 | 420 | 50 | 0.4 |
| 4 | D | 0.3 | 0.2 | 0.3 | 7950 | 740 | 110 | 0.5 |
| 5 | E | 0.3 | 0.3 | 0.3 | 12110 | 890 | 260 | 0.6 |
| 6 | F | 0.5 | 0.4 | 0.5 | 5420 | 1210 | 210 | 0.6 |
| 7 | G | 1 | 1 | 1.2 | 3210 | 580 | 370 | 0.4 |
| 8 | H | 2 | 3 | 2.5 | 3520 | 530 | 160 | 0.4 |
| 9 | I | 0.5 | 0.1 | 0.4 | 1420 | 900 | 680 | 0.4 |
| 10 | J | 1 | 0.5 | 0.5 | 210 | 160 | 2000 | 0.4 |

As shown in Table 1, it can be found that the height of the protrusions can be adjusted, for example, by the average particle diameter of the microparticles in the coating layer and by coating amount; and that the density of the protrusions can be adjusted, for example, by the content of the microparticles in the coating layer and by coating amount.

### 2. Production of Gas Bather Film

### Example 1

Base film 1 produced as described above was set in film-forming apparatus 30 and conveyed, as illustrated in the above-mentioned FIG. 3. Next, a magnetic field was applied between film-forming rolls 31 and 33, and electric power was supplied to each of film-forming rolls 31 and 33 to cause discharge between film-forming rolls 31 and 33, thus generating plasma. Next, a film-forming gas (a gas mixture of hexamethyldisiloxane (HMDSO) as a source gas and oxygen gas as a reactant gas (oxygen gas functions also as a discharge gas)) was supplied to the formed discharge region to form a thin film having gas barrier properties on the base film 1 using plasma CVD method, thus affording a gas barrier film. The wrap angles of the gas barrier film around film-forming rolls 31 and 33 were set at 260°. The thickness of the gas barrier film was 100 μm, and the thickness of the gas barrier layer was 150 nm. The film-forming conditions were set as follows:

### (Film-Forming Conditions)

Amount of source gas to be supplied: 50 sccm (Standard Cubic Centimeter per Minute; 0° C., based on 1 atm)

Amount of oxygen gas to be supplied: 500 sccm (0° C., based on 1 atm)

Degree of vacuum inside vacuum chamber: 3 Pa

Electric power to be applied from power source for plasma generation: 0.8 kW

Frequency of power source for plasma generation: 70 kHz

Conveying speed of film: 1.0 m/min

### Examples 2 to 6, Comparative Examples 1 to 5

Gas barrier films were obtained similarly to Example 1 except that the type of the base film was changed as shown in Table 2.

The moisture permeability and the flatness of the resultant gas barrier film were evaluated according to the methods as described below. These measurement results are shown in Table 2.

[Moisture Permeability]

The film was unwound from the roll of the resultant elongated gas barrier film, and cut into a predetermined size around 2,000 mm in the lengthwise direction from the end part of the termination of film-formation to employ the cut film as a test piece. The moisture permeability of the resultant test piece was measured using a steam permeability tester manufactured by MOCON, Inc. under conditions of 38° C. and 100% RH in accordance with the methods set forth in JIS K 7129B and ASTM F1249-90.

[Flatness]

The flatness of the bas barrier film was measured according to the following procedures:

1) First, as illustrated in the above-mentioned FIG. 4, strip S including both ends in the widthwise direction of the resultant elongated gas barrier film and being parallel to the widthwise direction of the film was cut out. As illustrated in FIG. 4, the width of strip S was set as 20 mm; and the length of strip S was set as the entire width of the gas barrier film (350 mm) Five pieces of strip S were cut out for every 100 mm in the lengthwise direction of the gas barrier film.
2) Next, as illustrated in the above-mentioned FIG. 5, the resultant strip S was disposed on stage 20 with the gas barrier layer being upward. Then, after the elapse of 10 minutes from the time when strip S was left at rest at 25° C. and at 50% RH, sites at which strip S was raised 1 mm or more from the surface of stage 20 (arrow parts) were counted along the lengthwise direction of strip S. Specifically, the number of the raised sites throughout the entire length in the lengthwise direction of strip S when being visually observed from one side a in the widthwise direction of strip S (number ca) was counted. It should be noted, however, that raised sites at both ends (in the lengthwise direction of strip S), among a plurality of raised sites, were not counted. Likewise, the number of the raised sites when being observed from the other side b in the widthwise direction of strip S (number cb) was also counted. Then, the larger value of the resultant numbers ca and cb was set as the “number c of raised sites.” A similar measurement was also conducted for 5 pieces of strip S.
3) The average value of the numbers c of the raised sites of the 5 pieces of strip S, obtained in the above step 2) was set as “flatness index.”

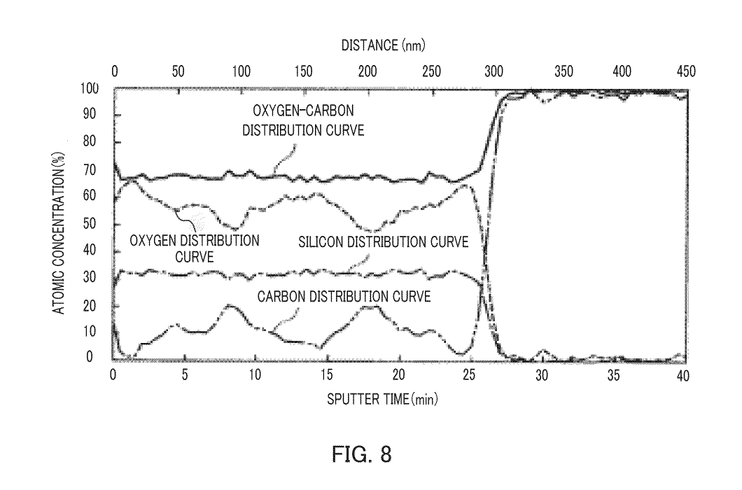

In addition, the composition distribution of the gas barrier layer formed in Examples in the thickness direction was measured according to the following method. The results are shown in FIG. 8.

[XPS Depth Profile Measurement]

XPS depth profile measurement of the gas barrier film obtained in Example 1 was conducted to obtain a silicon distribution curve, an oxygen distribution curve, a carbon distribution curve, and an oxygen-carbon distribution curve with the concentration (atomic %) of a specific atom as the ordinate and the sputter time (min) as the abscissa. The measurement conditions were set as follows:

Etching ion species: argon (Ar⁺)

Etching rate (value converted for SiO₂ thermal oxide film): 0.05 nm/sec

Etching interval (value converted for SiO₂): 10 nm

X-ray photoelectron spectrometer: model name “VG Theta Probe” manufactured by Thermo Fisher Scientific K.K.

Irradiated X-ray: single-crystal spectroscopy AlKα

X-ray spot and its size: elliptical shape of 800×400 μm

FIG. 8 is a schematic view illustrating the relationship between the content ratios (at %) of silicon atoms, oxygen atoms and carbon atoms and the distance (nm) from the surface of a gas barrier layer, in Example 1. The “distance (nm)” mentioned at the abscissa of the graph of FIG. 8 is a value calculated from sputter time and sputter speed.

TABLE 2

| | | Rear Surface Coating | | | | | | | | |
|---|---|---|---|---|---|---|---|---|---|---|
| | | | Silica Particles | | | Density of Rear Surface Protrusions | | | | |
| | | | Average | Content | | (number/mm²) | | | | |
| | | | Particle | Ratio | Coating | | | Protrusions B | Evaluation Results | |
| | Base Film | | Diameter | (% by | Amount | Protrusions A | | 100 nm or | Moisture | |
| | No. | Type | (μm) | mass) | (g/m²) | 10 to 100 nm | 50 to 100 nm | more | Permeability | Flatness |
| Comp. | 0 | None | | | | 300 | 110 | 160 | 0.013 | 6.2 |
| Ex. 1 | | | | | | | | | | |
| Comp. | 1 | A | | | 0.3 | 160 | 0 | 0 | 0.013 | 7 |
| Ex. 2 | | | | | | | | | | |
| Ex. 1 | 2 | B | 0.3 | 0.05 | 0.3 | 2000 | 160 | 0 | less than 0.01 | 2 |
| Ex. 2 | 3 | C | 0.3 | 0.1 | 0.3 | 4110 | 420 | 50 | less than 0.01 | 2 |
| Ex. 3 | 4 | D | 0.3 | 0.2 | 0.3 | 7950 | 740 | 110 | less than 0.01 | 2 |
| Comp. | 5 | E | 0.3 | 0.3 | 0.3 | 12110 | 890 | 260 | 0.02 | 2 |
| Ex. 3 | | | | | | | | | | |
| Ex. 4 | 6 | F | 0.5 | 0.4 | 0.5 | 5420 | 1210 | 210 | 0.012 | 2 |
| Ex. 5 | 7 | G | 1 | 1 | 1.2 | 3210 | 580 | 370 | 0.013 | 2 |
| Ex. 6 | 8 | H | 2 | 3 | 2.5 | 3520 | 530 | 160 | less than 0.01 | 2 |
| Comp. | 9 | I | 0.5 | 0.1 | 0.4 | 1420 | 900 | 680 | 0.035 | 2 |
| Ex. 4 | | | | | | | | | | |
| Comp. | 10 | J | 1 | 0.5 | 0.5 | 210 | 160 | 2000 | 0.08 | 2 |
| Ex. 5 | | | | | | | | | | |

As shown in FIG. 2, it can be found that the gas barrier films of Examples 1 to 6 have high flatness as well as low moisture permeability.

On the other hand, it can be found that, due to too low density of protrusions A, the slidability of the gas barrier films of Comparative Examples 1 and 2 on the film-forming roll is not improved, resulting in low flatness. On the other hand, it is considered that, due to too high density of protrusions A or protrusions B, all of the films of Comparative Examples 3 to 5 damaged the adjacent gas barrier layer when the film was incorporated into the roll, resulting in lowered moisture permeability.

As shown in FIG. 8, it can be found that the distribution curve of carbon in the gas barrier layer of the film of Example 1 is substantially sequential and has at least two extreme values. In addition, it can be found that the content ratio of carbon atoms in the gas barrier layer is 1 at % or more throughout the entire region in the film thickness direction.

### INDUSTRIAL APPLICABILITY

According to the present invention, it is possible to provide a gas barrier film having high gas bather properties and having excellent flatness.

### REFERENCE SIGNS LIST

10 Gas barrier film
11 Base
11 A Resin film
11B Coating layer
13 Gas barrier layer
30 Plasma CVD film-forming apparatus
31, 33 Film-forming roll
35, 37 Magnetic field generator
39 Power source
41 Gas supply tube
43 Feeding roll
45, 47, 49, 51 Conveying roll
53 Winding roll
60 Organic EL display device
61 Substrate
63 Organic EL element
65 Sealing substrate (transparent substrate)
67 Sealing resin layer
71 Lower electrode
73 Hole transport layer
75 Emitter layer
77 Electron transport layer
79 Upper electrode
100 Base
S1, S2, S Strip
G Gas barrier film

1. A roll of a gas barrier film obtained by winding a gas barrier film comprising a base and a gas barrier layer in a direction orthogonal to a width the film,
wherein:
the gas barrier layer contains silicon atoms, oxygen atoms and carbon atoms;
a carbon distribution curve with a distance from a surface of the gas barrier layer in a film thickness direction as X value and a content ratio of the carbon atoms relative to a total amount of the silicon atoms, the oxygen atoms and the carbon atoms as Y value has a maximum value and a minimum value;
a surface of the base, opposite to a side on which the gas barrier layer is disposed, has protrusions A having a height of 10 nm or more and less than 100 nm from a roughness center plane at a density of 500 to 10,000/mm², and protrusions B having a height of 100 nm or more from a roughness center plane at a density of 0 to 500/mm²;
the base has a haze of 1% or less measured in accordance with JIS K-7136; and
when a strip with a width of 20 mm including both ends in a widthwise direction of the gas barrier film and being obtained by cutting in a direction parallel to the widthwise direction of the gas barrier film is kept for 10 minutes at 25° C. and at 50% RH on a stage, and then the number of sites raised 1 mm or more from a surface of the stage is counted in a lengthwise direction of the strip, a flatness index defined as the number of sites raised 1 mm or more from the surface of the stage per total length of the strip is within a range of from 0 to 5.

2. The roll of a gas barrier film according to claim 1, wherein a thickness of the base is more than 25 μm and 200 μm or less.

3. The roll of a gas barrier film according to claim 1, wherein the base has a coating layer containing microparticles on a surface opposite to the side on which the gas barrier layer is disposed.

4. A process for producing a gas barrier film using a plasma CVD film-forming apparatus including a vacuum chamber, a pair of film-forming rolls disposed inside the vacuum chamber and having rotation axes being approximately parallel to each other, with a magnetic field-generating member being contained therein, and a power source that provides a potential difference between the pair of film-forming rolls,
wherein:
a film formation surface of an elongated base wound around one of the film-forming rolls and a film formation surface of the elongated base wound around the other of the film-forming rolls face each other across film-forming space, as the elongated base is conveyed while being wound around the pair of film-forming rolls, with a wrap angle of the base wound around the film-forming rolls being 150° or more;
the process comprises: supplying a film-forming gas containing an organic silicon compound gas and oxygen gas to the film-forming space; providing a potential difference between the pair of film-forming rolls with the power source to generate discharge plasma in the film-forming space; and forming a thin film gas barrier layer containing silicon atoms, oxygen atoms and carbon atoms on the film formation surface of the base;
the base has a haze of 1% or less measured in accordance with JIS K-7136; and
a surface of the base to be in contact with the film-forming roll has protrusions A having a height of 10 nm or more and less than 100 nm from a roughness center plane at a density of 500 to 1,000/mm², and protrusions B having a height of 100 nm or more from a roughness center plane at a density of 0 to 500/mm².

5. The process for producing a gas barrier film according to claim 4,
wherein a thickness of the base is more than 25 μm and 200 μm or less.

6. The process for producing a gas barrier film according to claim 4, wherein the base has a coating layer containing microparticles on a surface to be in contact with the film-forming roll.

7. The roll of a gas barrier film according to claim 1, wherein at a surface opposite to a surface having the gas barrier layer has the protrusions A at a density of 2,000 to 8,000/mm².

8. The roll of a gas barrier film according to claim 1, wherein protrusions A′ having a height of 50 nm or more and less than 100 nm from a roughness center plane exist at a density of 1,000/mm² or less among the protrusions A.

9. The roll of a gas barrier film according to claim 1, wherein protrusions A′ having a height of 50 nm or more and less than 100 nm from a roughness center plane exist at a density of 600/mm² or less among the protrusions A.

10. The roll of a gas barrier film according to claim 9, wherein the protrusions B exist at a density of 150/mm² or less.

11. The roll of a gas barrier film according to claim 10, wherein the base has a haze of 0.8% or less measured in accordance with JIS K-7136.

12. The roll of a gas barrier film according to claim 11, wherein a content ratio of silicon atoms in the gas barrier layer (amount of silicon atoms/(amount of silicon atoms+amount of oxygen atoms+amount of carbon atoms)) is 25 to 45 at %.

13. The roll of a gas barrier film according to claim 1, wherein the protrusions B exist at a density of 300/mm² or less.

14. The roll of a gas barrier film according to claim 1, wherein the protrusions B exist at a density of 150/mm² or less.

15. The roll of a gas barrier film according to claim 3, wherein an average particle diameter of the microparticles is 30 nm to 300 nm.

16. The roll of a gas barrier film according to claim 15, wherein a content of the microparticles is within a range of from 0.001 to 10% by mass relative to a total of the coating layer.

17. The roll of a gas barrier film according to claim 16, wherein the coating layer has a cured product of a curable resin.

18. The roll of a gas barrier film according to claim 1, wherein the base has a haze of 0.8% or less measured in accordance with JIS K-7136.

19. The roll of a gas barrier film according to claim 1, wherein a content ratio of silicon atoms in the gas barrier layer (amount of silicon atoms/(amount of silicon atoms+amount of oxygen atoms+amount of carbon atoms)) is 25 to 45 at %.
